(19) United States
(12) Patent Application Publication
(10) Pub. No.: US 2024/0404751 A1
(43) Pub. Date: Dec. 5, 2024

(54) CAPACITOR AND METHOD OF FORMING THE SAME

(71) Applicants: Semiconductor Manufacturing International (Shanghai) Corporation, Shanghai (CN); Semiconductor Manufacturing International (Beijing) Corporation, Beijing (CN)

(72) Inventor: Xingkai HUANG, Beijing (CN)

(21) Appl. No.: 18/652,377

(22) Filed: May 1, 2024

(30) Foreign Application Priority Data
May 30, 2023 (CN) 202310628968.8

(51) Int. Cl. H01G 4/008; H01G 4/01

(52) U.S. Cl. CPC H01G 4/008; H01G 4/01

(57) ABSTRACT

A capacitor includes: a substrate including a center area and a peripheral area surrounding the center area; a plurality of active parts disposed in the center area and the peripheral area; an electrode structure including a first insulation layer, a first electrode plate, a second insulation layer, and a second electrode plate; one or more first openings disposed in the electrode structure in the peripheral area exposing a part of the top surface of each of the plurality of active parts in the peripheral area; one or more second openings disposed in the second electrode plate and the second insulation layer in the peripheral area exposing a part of the surface of the first electrode plate in the peripheral area; and a plurality of first plugs disposed in the one or more first openings and a plurality of second plugs disposed in the one or more second openings.

### CROSS-REFERENCE TO RELATED APPLICATION

This application claims priority to Chinese Patent Application No. 202310628968.8, filed on May 30, 2023, and the entire content of which is incorporated herein by reference.

### TECHNICAL FIELD

The present disclosure relates to the technical field of semiconductor technology, and more particularly, to a capacitor and a method of forming the capacitor.

### BACKGROUND

With the development of semiconductor technology and driven by Moore's Law, process nodes in the semiconductor technology continue to become smaller, such that integrated circuits having smaller size, higher circuit precision, and higher circuit complexity lead the trend. In the development process of integrated circuits, while the functional density (i.e., the number of interconnect structures per chip) gradually increases, the geometric size gradually decreases, which correspondingly increases the difficulty and complexity of integrated circuit manufacturing.

In recent years, flash memories, being important components, have been widely used in integrated circuit chips required in various scenarios such as automobiles, consumer electronics, and industrial products. Polysilicon-insulator-polysilicon (PIP) capacitors are widely used as capacitive elements in flash memories due to their advantages such as desired compatibility and simplicity in manufacturing process thereof.

However, in the existing technology, when large capacitance is needed, the capacitor plate often occupies a large area, thereby increasing the chip size and making it difficult to shrink the chip size.

### SUMMARY

One aspect of the present disclosure provides a capacitor. The capacitor includes a substrate including a center area and a peripheral area surrounding the center area; a plurality of active parts disposed in the center area and the peripheral area, first grooves being formed between adjacent active parts; an electrode structure including a first insulation layer, a first electrode plate, a second insulation layer, and a second electrode plate that are stacked in sequence, the electrode structure being disposed in the first grooves and on the top surface of each of the plurality of active parts; one or more first openings disposed in the electrode structure in the peripheral area exposing a part of the top surface of each of the plurality of active parts in the peripheral area; one or more second openings disposed in the second electrode plate and the second insulation layer in the peripheral area exposing a part of the surface of the first electrode plate in the peripheral area; and a plurality of first plugs disposed in the one or more first openings and a plurality of second plugs disposed in the one or more second openings.

Another aspect of the present disclosure provides a method of forming a capacitor. The method includes: providing a substrate; etching the substrate including a center area and a peripheral area surrounding the center area to form a plurality of active parts in the center area and the peripheral area, and first grooves between adjacent active parts; forming an electrode structure on the surface of the substrate, in the first grooves, and on the top surface of each of the plurality of active parts, the electrode structure including a first insulation layer, a first electrode plate, a second insulation layer, and a second electrode plate that are stacked in sequence; forming one or more first openings in the electrode structure in the peripheral area exposing a part of the top surface of each of the plurality of active parts; forming one or more second openings in the second electrode plate and the second insulation layer in the peripheral area exposing a part of the surface of the first electrode plate; and forming a plurality of first plugs in the one or more first openings and a plurality of second plugs in the one or more second openings.

### BRIEF DESCRIPTION OF THE DRAWINGS

FIGS. 1-21 are structural diagrams showing various stages of a process of forming an exemplary capacitor according to some embodiments of the present disclosure; and

FIG. 22 is a flowchart of a method of forming an exemplary capacitor according to some embodiments of the present disclosure.

### DETAILED DESCRIPTION OF THE EMBODIMENTS

As mentioned in the background section, in existing capacitors, when the large capacitance is needed, the capacitor plate often occupies a large area, thereby increasing the chip size and making it difficult to shrink the chip size.

The present disclosure provides a capacitor. The capacitor includes: a substrate; a first electrode plate disposed on the substrate; a first insulation layer and a second electrode plate disposed on the first electrode plate; and a second insulation layer and a third electrode plate disposed on the second electrode plate. The first electrode plate, the second electrode plate, and the third electrode plate are all parallel to a surface of the substrate. Thus, the first electrode plate, the first insulation layer, and the second electrode plate form a first capacitor, and the second electrode plate, the second insulating layer, and the third electrode plate form a second capacitor. When the capacitor needs to achieve a large capacitance, a common design method is to increase areas of the first electrode plate, the second electrode plate, and the third electrode plate, thereby increasing the capacitance. However, such capacitor design increases a horizontal operation area of a chip, which makes it difficult to achieve device integration and miniaturization.

To solve the above technical problems, the present disclosure also provides a method for forming a capacitor. The method includes: etching the substrate to form various areas and a plurality of active parts, with first grooves between adjacent active parts; and forming a first insulation layer, a first electrode plate, a second insulation layer, and a second electrode plate in the first grooves. The first electrode plate and the first insulation layer are disposed on a top surface of each of the plurality of active parts, and the second electrode plate and the second insulation layer are disposed on a surface of the first electrode plate. As such, the plurality of active parts, and the first insulation layer, and the first electrode plate disposed on both sides of the active part and on the top surface of each of the plurality of active parts together form a three-sided capacitor structure. The first electrode plate, the second insulation layer, and the second electrode plate may also form another three-sided capacitor structure on both sides and the top surface of each of the plurality of active parts, thereby increasing capacitance density. At the same time, because the first electrode plate is an interconnected integral electrode plate and the second electrode plate is another interconnected integral electrode plate, conductive plugs can be arranged only in a peripheral area of the substrate, thereby substantially reducing the number of conductive plugs required for the electrical interconnection and minimizing occurrence of short circuits in the electrical interconnection. The first electrode plate and the second electrode plate disposed in a center area are ensured to have large operation areas. Thus, the capacitance is increased and the process of forming the electrical interconnection has less impact on the device structure in the center area.

To make the above objectives, features, and beneficial effects of the present disclosure more obvious and understandable, various embodiments of the present disclosure will be described in detail below with reference to the accompanying drawings.

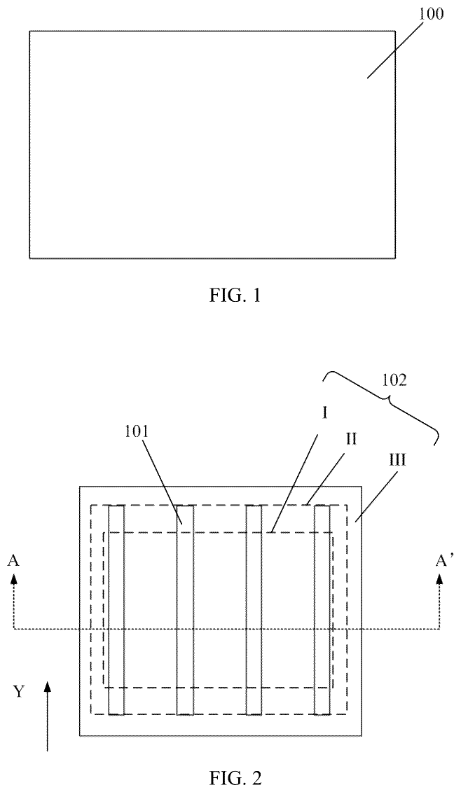

FIGS. 1-21 are structural diagrams showing various stages of a process of forming an exemplary capacitor according to some embodiments of the present disclosure. As shown in FIG. 1, a substrate 100 is provided.

The material of the substrate 100 includes silicon, silicon germanium, silicon carbide, silicon on insulator (SOI), germanium on insulator (GOI), etc. For example, in one embodiment, the material of the substrate 100 is silicon.

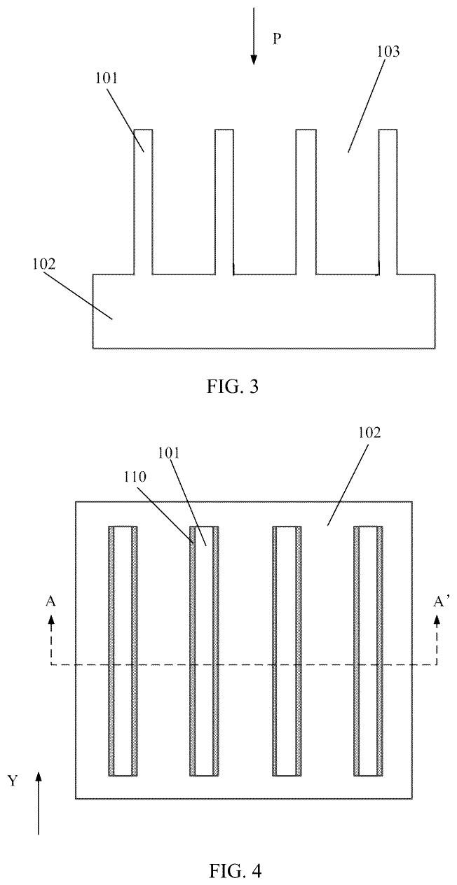

Referring to FIGS. 2 and 3, FIG. 2 is a top view of FIG. 3 along P direction, and FIG. 3 is a schematic cross-sectional view of FIG. 2 along AA′ direction. The substrate 100 is etched to form a substrate 102. The substrate 102 includes a center area I, a peripheral area II surrounding the center area I, and an isolation area III surrounding the center area I and the peripheral area II. A plurality of discrete active parts 101 (also known as active parts) are formed in the center area I and the peripheral area II. First grooves 103 are formed between adjacent active parts 101.

In some embodiments, each of the plurality of active parts 101 extends along a first direction Y. The plurality of active parts 101 are arranged parallel to each other, and the plurality of active parts 101 are arranged perpendicular to a surface of the substrate 102.

The peripheral area II defines an area where conductive plugs of a capacitor are subsequently formed. The center area I defines an area where a core device structure in the capacitor is formed. The isolation area III defines an area where an isolation structure is subsequently formed.

In some embodiments, the process of etching the substrate 100 includes a dry etching process.

In some embodiments, the material of the plurality of active parts 101 includes silicon. The plurality of active parts 101 may contain P-type conductive ions or N-type conductive ions.

In some embodiments, spacing between adjacent active parts 101 ranges from 100 nanometers to 1,000 nanometers.

Next, an electrode structure is formed on the surface of the substrate 102, inside the first grooves 103, and on a top surface of each of the plurality of active parts 101. The electrode structure includes: a first insulation layer, a first electrode plate, a second insulation layer, and a second electrode plate, that are sequentially stacked.

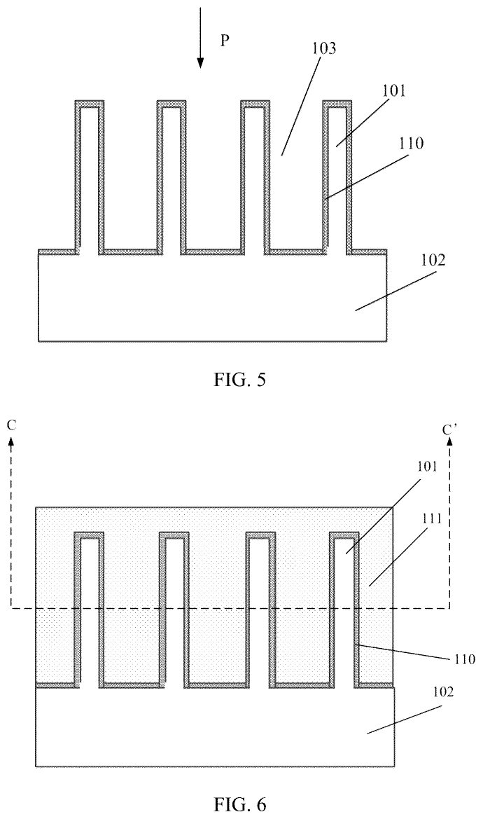

Referring to FIGS. 4 and 5, FIG. 4 is a top view of FIG. 5 along the P direction, FIG. 5 is a schematic cross-sectional view of FIG. 4 along the AA′ direction. The first insulation layer 110 is formed on the surface of the substrate 102 exposed by the first grooves 103, on sidewall surfaces on both sides of each of the plurality of active parts 101, and the top surface of each of the plurality of active parts 101.

In some embodiments, the material of the first insulation layer 110 includes silicon oxide or silicon nitride.

It should be noted that, for convenience of comprehension, the first insulation layer 110 on the surface of the substrate 102 and the top surface of the active part 101 are omitted in FIG. 5.

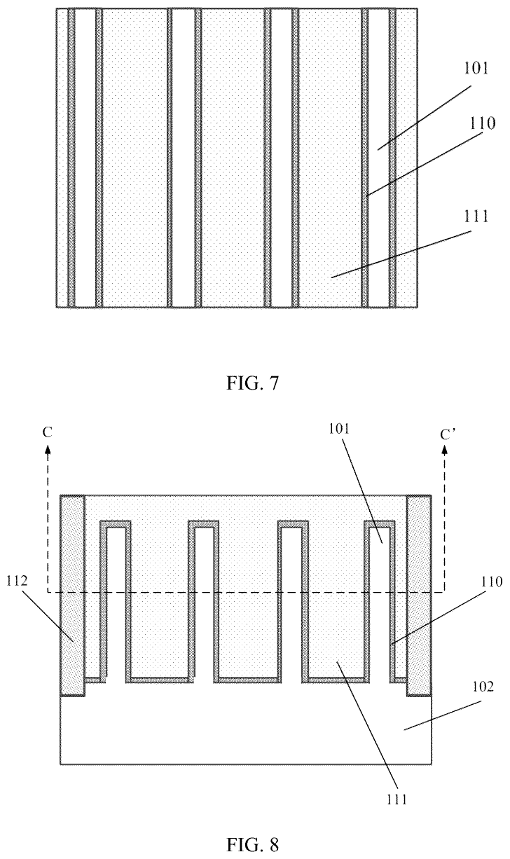

Referring to FIGS. 6 and 7, a view direction of FIG. 6 is consistent with a view direction of FIG. 5. FIG. 7 is a schematic cross-sectional view along CC′ direction of FIG. 6. A first material layer 111 is formed in the first grooves 103 and on a surface of the first insulation layer 110 disposed on the top surface of each of the plurality of active parts 101. The first material layer 111 is planarized.

A top surface of the first material layer 111 is higher than the top surface of each of the plurality of active parts 101. In some embodiments, the material of the first material layer 111 includes polysilicon.

In some embodiments, the first material layer 111 provides raw materials for the subsequently formed first electrode plate.

It should be noted that the cross-sectional direction (i.e., CC′ direction) of the schematic cross-sectional view shown in FIG. 7 is parallel to the surface of the substrate 102.

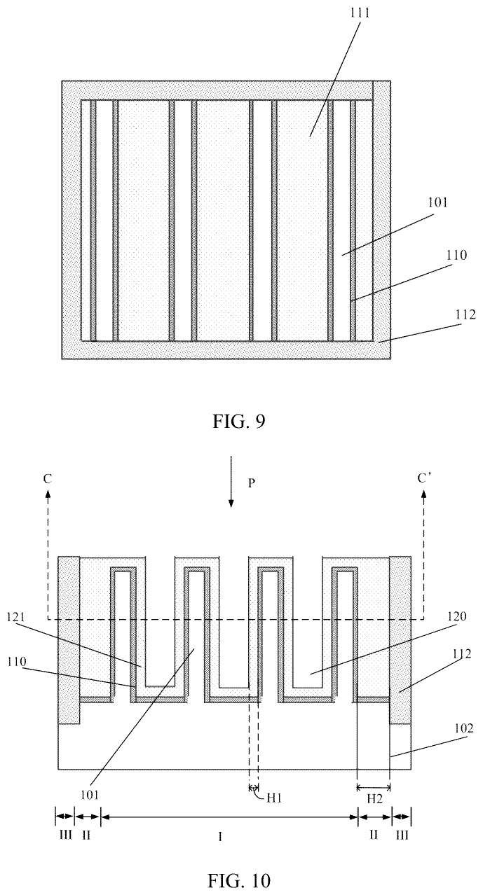

Referring to FIGS. 8 and 9, a view direction of FIG. 8 is consistent with the view direction of FIG. 6. FIG. 9 is a schematic cross-sectional view along CC′ of FIG. 8. An isolation structure 112 is formed in the isolation area III, and a surface of the isolation structure 112 is flush with the top surface of the first material layer 111.

In some embodiments, the isolation structure 112 provides a function to electrically isolate each capacitor structure in the center area I and the peripheral area II from other surrounding device structures.

In some embodiments, the method of forming the isolation structure 112 includes: etching a part of the isolation area III; depositing an isolation material layer (not shown) on the surface of the isolation area III; planarizing the isolation material layer to form the isolation structure 112 until the top surface of the first material layer 111 is exposed.

A top surface of the isolation structure 112 is flush with the top surface of the first material layer 111 and is higher than the top surface of each of the plurality of active parts 101, and a bottom surface of the isolation structure 112 is lower than the top surface of the substrate 102.

It should be noted that the cross-sectional direction (i.e., CC′ direction) of the schematic cross-sectional view shown in FIG. 9 is parallel to the surface of the substrate 102.

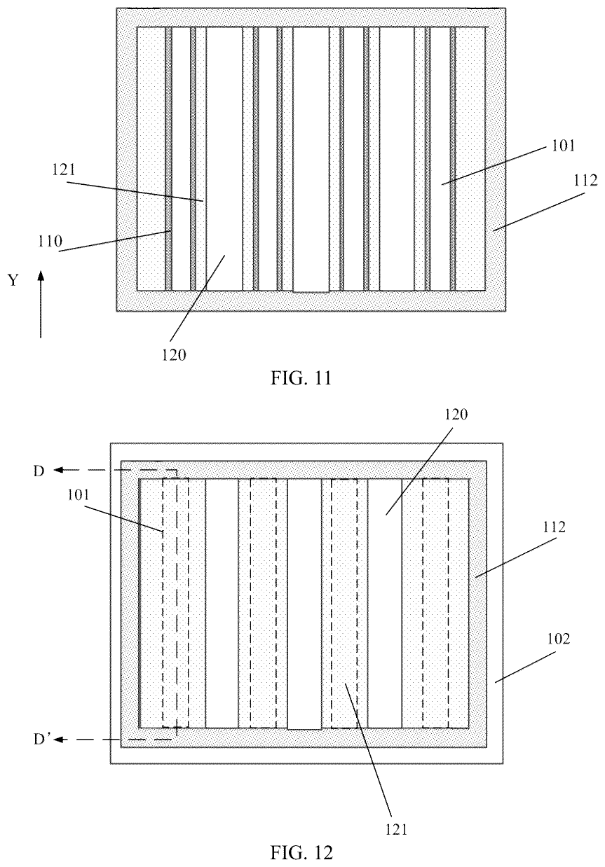

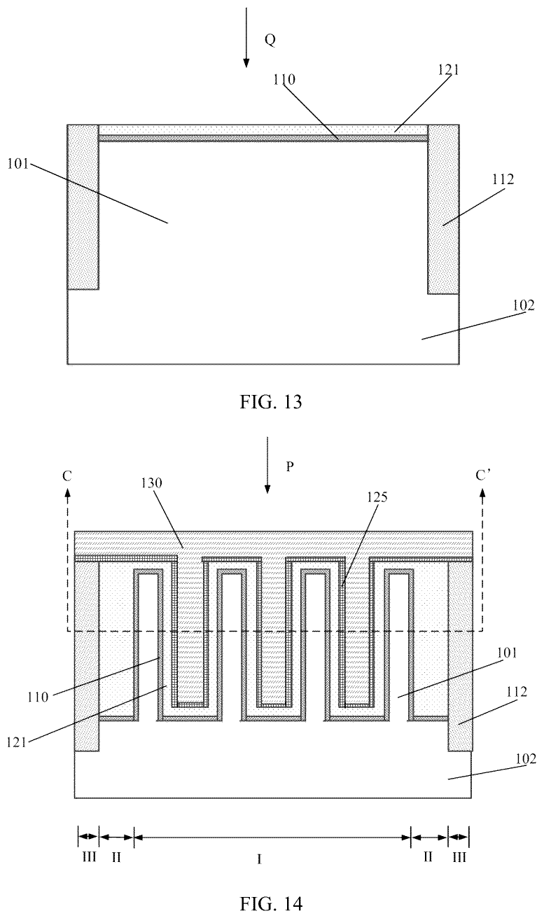

Referring to FIGS. 10 to 13, a view direction of FIG. 10 is consistent with the view direction of FIG. 8. FIG. 11 is a schematic cross-sectional view of FIG. 10 along CC′ direction. FIG. 12 is a top view of FIG. 10 along P direction. FIG. 12 is also a top view of FIG. 13 along Q direction. FIG. 13 is a schematic cross-sectional view of FIG. 12 along DD′ direction.

Second grooves 120 are formed in the first material layer 111. The bottoms of the second grooves 120 are higher than the surface of the substrate 102. The first material layer 111 becomes the first electrode plate 121.

In some embodiments, the first electrode plate 121 is formed on the surface of the first insulation layer 110. The first electrode plate 121 is located in the first grooves 103 and on the top surface of each of the plurality of active parts 101. The first electrode plate 121 located in the first grooves 103 includes the second grooves 120.

In some embodiments, the material of the first electrode plate 121 includes polysilicon.

The first insulation layer 110 and the first electrode plate 121 are formed on the sidewall surfaces on both sides of each of the plurality of active parts 101. The first electrode plate 121 and the first insulation layer 110 are also formed on the top surface of each of the plurality of active parts 101. Thus, the plurality of active parts 101, the first insulation layer 110, and the first electrode plate 121 together form a three-sided capacitor structure on both sides and the top surface of each of the plurality of active parts 101, thereby utilizing a vertical operation space of the chip. While the electrode plate of the capacitor occupies a large area, a horizontal operation area of the chip is controlled to be small to increase the capacitance density.

At the same time, because the first electrode plate 121 is an interconnected integral electrode plate, in an electrical interconnection process of the first electrode plate 121, the conductive plugs can be arranged only in the peripheral area II of the substrate 102, substantially reducing the number of conductive plugs required for the electrical interconnection and minimizing occurrence of short circuits of the electrical interconnection. The first electrode plate 121 in the center area I is ensured to have a large operation area, thereby increasing the capacitance and reducing the impact of the electrical interconnection on the device structure in the center area I.

In some embodiments, a distance from the top surface of the first electrode plate 121 to the top surface of the first insulation layer 110 ranges from 20 nanometers to 200 nanometers, thereby ensuring that the first electrode plate 121 become the interconnected integral electrode plate.

In some embodiments, a thickness H2 of the first electrode plate 121 in the peripheral area II in a direction perpendicular to the sidewall of the plurality of active parts 101 is greater than a thickness H1 of the first electrode plate 121 in the center area I in the direction perpendicular to the sidewall of the plurality of active parts 101. In the subsequent process of forming the conductive plugs on the surface of the first electrode plate 121, the conductive plugs are formed on the surface of the first electrode plate 121 in the peripheral area II. Thus, the thickness H2 of the first electrode plate 121 in the peripheral area II needs to be thicker to meet process requirements of forming the conductive plugs. The thickness H1 of the first plate 121 in the center area I may be thinner to meet side reduction requirements of small size device capacitors without compromising the electrical interconnection process.

Specifically, the thickness H1 of the first electrode plate 121 in the center area I in the direction perpendicular to the sidewall of the plurality of active parts 101 ranges from 20 nanometers to 200 nanometers. The thickness H2 of the first electrode plate 121 in the peripheral area II in the direction perpendicular to the sidewall of the plurality of active parts 101 ranges from 40 nanometers to 200 nanometers.

In some embodiments, each of the second grooves 120 extends in the first direction Y. The extension direction of each of the second grooves 120 is parallel to the extension direction of each of the plurality of active parts 101. The first direction Y is parallel to the surface of the substrate 102.

In some embodiments, the top surface of the first electrode plate 121 is flush with the top surface of the isolation structure 112 in the isolation area III.

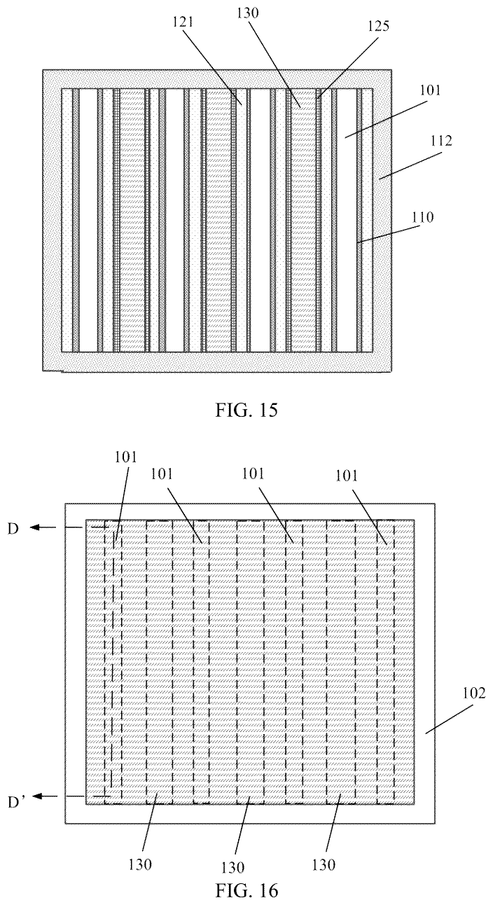

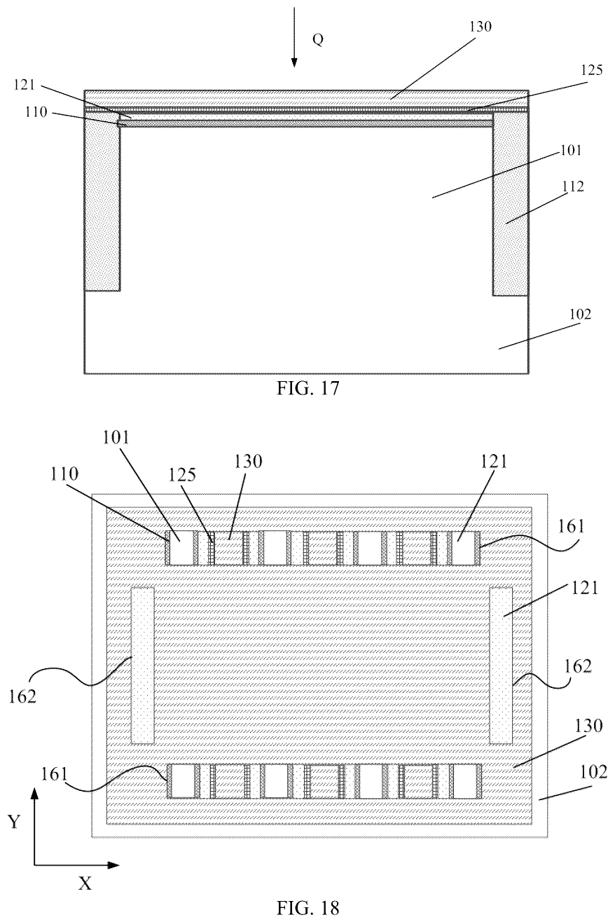

Referring to FIGS. 14-17, a view direction of FIG. 14 is consistent with the view direction of FIG. 10. FIG. 15 is a schematic cross-sectional view of FIG. 14 along CC′ direction. FIG. 16 is a top view of FIG. 14 along P direction, and FIG. 16 is also a top view of FIG. 17 along Q direction. FIG. 17 is a schematic cross-sectional view of FIG. 16 along DD′ direction.

A second insulation layer 125 is formed in the second grooves 120 and on the top surface of the first electrode plate 121. A second electrode plate 130 is formed in the second grooves 120 and on the surface of the second insulation layer 125 on the top of each of the plurality of active parts 101. The second electrode plate 130 is filled in the second grooves 120. The second electrode plate 130 is also disposed on the surface of the second insulation layer 125 on the top surface of the first electrode plate 121. The second electrode plate 130 and the second insulation layer 125 are also formed on the surface of the isolation structure 112.

Specifically, after the second electrode plate 130 is formed, a part of the second insulation layer 125 and a part of the second electrode plate 130 are disposed in the isolation area III. Parts of the plurality of active parts 101, the first electrode plate 121, the second electrode plate 130, the first insulation layer 110, and the second insulation layer 125 are disposed in the peripheral area II.

In some embodiments, the material of the second electrode plate 130 includes polysilicon.

Because the first electrode plate 121 is higher than the plurality of active parts 101 and the second electrode plate 130 is higher than the first electrode plate 121, the first electrode plate 121 is an interconnected integral electrode plate, and the second electrode plate 130 is also an interconnected integral electrode plate.

In some embodiments, the first insulation layer 110, the first electrode plate 121, the second insulation layer 125, and the second electrode plate 130 are disposed in the first grooves 103 between adjacent active parts 101. The first electrode plate 121 and the first insulation layer 110 are also disposed on the top surface of each of the plurality of active parts 101. The second electrode plate 130 and the second insulation layer 125 are also disposed on the surface of the first electrode plate 121. Thus, the plurality of active parts 101, the first insulation layer 110, and the first electrode plate 121 together may form a three-sided capacitor structure on both sides and the top surface of each of the plurality of active parts 101. The first electrode plate 121, the second insulation layer 125, and the second electrode plate 130 may also form a polysilicon-insulator-polysilicon (PIP) three-sided capacitor structure on both sides and the top surface of each of the plurality of active parts 101. Thus, the vertical operation space of the chip can be utilized more efficiently. At the same time that the large capacitor plate area can be maintained, the horizontal operation space of the chip is controlled to be small to increase the capacitance density.

Further, because the first electrode plate 121 is an interconnected integral electrode plate, and the second electrode plate 130 is also an interconnected integral electrode plate, the conductive plugs may be arranged only in the peripheral area II of the substrate 102. The number of conductive plugs required for the electrical interconnection can be substantially reduced. Occurrence of short circuits of the electrical interconnection can be minimized. The first electrode plate 121 in the center area I is ensured to have a large operation area, thereby increasing the capacitance and reducing the impact of the electrical interconnection on the device structure in the center area I

Further, the plurality of active parts 101 serve as a capacitor plate and are formed by etching the substrate. Thus, the substrate can be used as a raw material to simplify the formation process.

In addition, the first electrode plate 121 is an interconnected integral electrode plate, and the second electrode plate 130 is also an interconnected integral electrode plate. Thus, the plurality of active parts 101, the first insulation layer 110, the first electrode 121, the second insulation layer 125, and the second electrode plate 130 together form two three-sided capacitor structures to function as one capacitor, thereby improving the integration level of the capacitor and improving the uniformity of electrical performance in each area of the capacitor.

In some embodiments, a distance from the top surface of the second electrode plate 130 to the top surface of the second insulation layer 125 ranges from 20 nanometers to 200 nanometers, thereby ensuring that the second electrode plate 130 become an interconnected integral electrode plate.

In some embodiments, the material of the second insulating layer 125 includes silicon oxide or silicon nitride.

Referring to FIG. 18, a view direction of FIG. 18 is consistent with the view direction of FIG. 16. A first opening 161 is formed in the second electrode plate 130, the second insulation layer 125, the first electrode plate 121, and the first insulation layer 110 in the peripheral area II. The first opening 161 exposes a part of the top surface of each of the plurality of active parts 101 in the peripheral area II. A second opening 162 is formed in the second electrode plate 130 and the second insulation layer 125 in the peripheral area II. The second opening 162 exposes a part of the surface of the first electrode plate 121 in the peripheral area II.

In some embodiments, the first opening 161 and the second opening 162 provide an accommodating space for the subsequently formed conductive plugs. The conductive plugs are used to electrically connect the plurality of active parts 101, the first electrode plate 121, and the second electrode plate 130 to an external circuit.

In some embodiments, the first opening 161 includes one or more first openings 161. The second opening 162 includes one or more second openings 162. Each of the one or more first openings 161 extends along a second direction X. Each of the one or more second openings 161 extends along the first direction Y. The first direction Y and the second direction X are both parallel to the surface of the substrate 102. The first direction Y and the second direction X are perpendicular to each other.

In some embodiments, the one or more first openings 161 simultaneously expose parts of the top surface of each of the plurality of active parts 101, the surface of the first electrode plate 121, the surface of the second electrode plate 130, the surface of the first insulation layer 110, and the surface of the second insulation layer 125 in the peripheral area II. The method of forming the one or more first openings 161 includes: forming a first mask layer (not shown) on the surface of the second electrode plate 130. The first mask layer exposes a part of the second electrode plate 130 in the peripheral area II. The first mask layer is used as a mask to etch the second electrode plate 130, the second insulation layer 125, the first electrode plate 121, and the first insulation layer 110 until the top surface of each of the plurality of active parts 101 is exposed, thereby forming the one or more first openings 161.

In some embodiments, the method for forming the one or more second openings 162 includes: forming a second mask layer (not shown) on the surface of the second electrode plate 130. The second mask layer exposes a part of the second electrode plate 130 in the peripheral area II. The second mask layer is used as a mask to etch the second electrode plate 130 and the second insulation layer 125 until the surface of the first electrode plate 121 is exposed, thereby forming the one or more second openings 162.

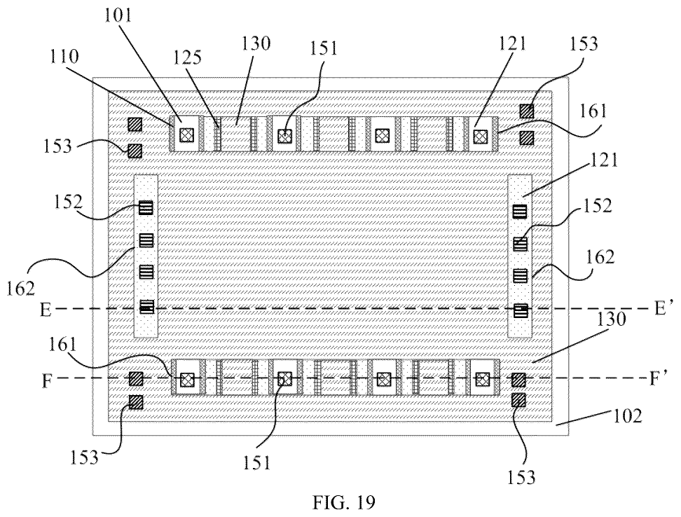

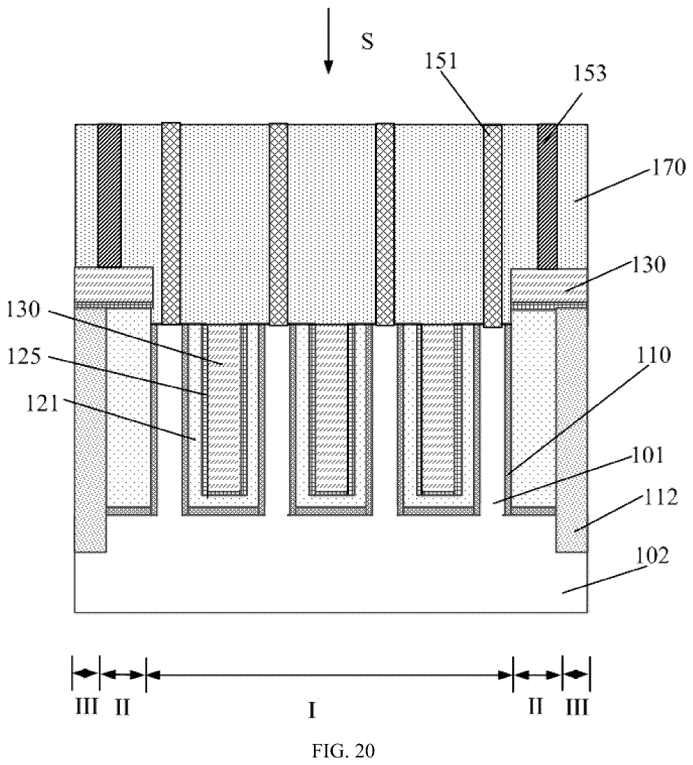

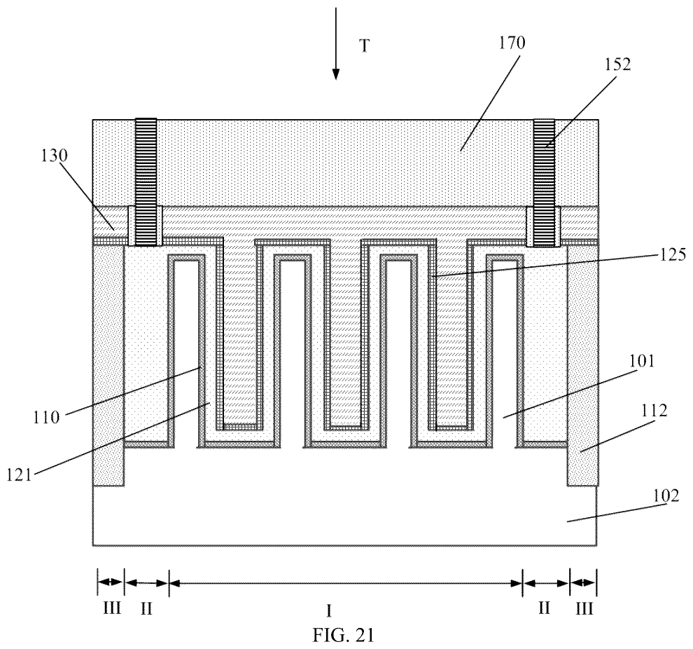

Referring to FIGS. 19 to 21, a view direction of FIG. 19 is consistent with the view direction of FIG. 18. FIG. 19 is a top view of FIG. 20 along S direction. FIG. 19 is also a top view of FIG. 21 along T direction. FIG. 20 is a schematic cross-sectional view along FF′ direction in FIG. 19. FIG. 21 is a schematic cross-sectional view along EE′ direction in FIG. 19.

An interlayer dielectric layer 170 is formed in the one or more first openings 161 and in the one or more second openings 162, and on the surface of the second electrode plate 130. A plurality of first plugs 151 are formed on the top surface of each of the plurality of active parts 101 exposed by the first opening 161. A plurality of second plugs 152 are formed on the surface of the first electrode plate 121 exposed by the one or more second openings 162. A plurality of third plugs 153 are formed on the surface of the second electrode plate 130 in the peripheral area II.

The plurality of first plugs 151, the plurality of second plugs 152, and the plurality of third plugs 153 are formed in the interlayer dielectric layer 170.

It should be noted that, for convenience of comprehension, the interlayer dielectric layer 170 is omitted in FIG. 19.

In some embodiments, the plurality of first plugs 151 are disposed on the top surface of each of the plurality of active parts 101. The plurality of second plugs 152 are disposed on the top surface of the first electrode plate 121. The top surface of the first electrode plate 121 is higher than the top surface of each of the plurality of active parts 101. Thus, a bottom surface of each of the plurality of first plugs 151 is lower than a bottom surface of each of the plurality of second plugs 152. The plurality of third plugs 153 are disposed on the top surface of the second electrode plate 130. The top surface of the second electrode plate 130 is higher than the top surface of the first electrode plate 121. The bottom surface of each of the plurality of second plugs 152 is lower than the bottom surface of each of the plurality of third plugs 153. The bottom surfaces of each of the plurality of first plugs 151, each of the plurality of second plugs 152, and each of the plurality of third plugs 153 are not on a same plane. Thus, windows of the process of forming the conductive plugs are increased, a wiring space is better utilized, interference between the conductive plugs is reduced, and detects such as circuit breakage are reduced.

In some embodiments, the first electrode plate 121 is an interconnected integral electrode plate, and the second electrode plate 130 is also an interconnected integral electrode plate. The first electrode plate 121 and the second electrode plate 130 may be electrically connected through a few conductive plugs. In addition, in terms of a layout of the conductive plugs, the conductive plugs may be arranged only in the peripheral area II of the substrate 102, thereby substantially reducing the number of conductive plugs required for the electrical interconnection and minimizing the occurrence of short circuits in the electrical interconnection. At the same time, the integrity of the surface structure of the first electrode plate 121, the second electrode plate 130, and the plurality of active parts 101 in the center area I is maintained, and the impact of the conductive plug formation process on a core capacitor structure in the center area I is reduced. This ensures that the first electrode plate 121 and the second electrode plate 130 occupy a large operation area in the center area I, thereby increasing the capacitance density.

In some other embodiments, the plurality of third plugs 153 may also be disposed on the surface of the second electrode plate in the isolation area III, thereby further reducing the impact of the conductive plug formation process on the core capacitor structure in the center area I and expanding the plug wiring space.

In some embodiments, after forming the plurality of first plugs 151, the plurality of second plugs 152, and the plurality of third plugs 153, a first electrical interconnection layer (not shown) is formed on the surfaces of the plurality of first plugs 151 and the plurality of third plugs 153. The first electrical interconnection layer electrically connects the plurality of third plugs 153 and the plurality of first plugs 151. A second electrical interconnection layer (not shown) is formed on the surfaces of the plurality of second plugs 152. Thus, the plurality of active parts 101, the first insulation layer 110, and the first electrode plate 121 function as a first capacitor structure, and the first electrode plate 121, the second insulation layer 125, and the second electrode plate 130 function as a second capacitor structure. The first capacitor structure and the second capacitor structure are connected in parallel.

In some embodiments, the material of the plurality of active parts 101 is silicon. The materials of the first electrode plate 121 and the second electrode plate 130 are both polysilicon. The plurality of active parts 101, the first insulation layer 110, and the first electrode plate may form a three-sided capacitor structure on both sides and the top surface of each of the plurality of active parts 101. The first electrode plate 121, the second insulation layer 125, and the second electrode plate 130 may also form a three-sided capacitor structure on both sides and the top surface of each of the plurality of active parts 101. Thus, two three-sided capacitor structures are formed to connect in parallel, and the vertical operation space of the chip is efficiently utilized to increase the capacitance density. The capacitor structure is suitable for small-sized capacitor scenarios, especially for Nor Flash devices with nodes below 45 nm. The capacitor structure can take into account the needs of device size reduction and capacitance density design.

In addition, the spatially centralized wiring method of the plurality of first plugs 151, the plurality of second plugs 152, and the plurality of third plugs 153 also provides a wiring design solution with large process windows for small-sized capacitor structures, thereby improving the stability of the electrical interconnections.

In the embodiments of the present disclosure, the method of forming the capacitor includes: etching the substrate to form various areas and a plurality of active parts, with first grooves between adjacent active parts; and forming a first insulation layer, a first electrode plate, a second insulation layer, and a second electrode plate in the first grooves. The first electrode plate and the first insulation layer are disposed on a top surface of each of the plurality of active parts, and the second electrode plate and the second insulation layer are disposed on a surface of the first electrode plate. As such, the plurality of active parts, and the first insulation layer, and the first electrode plate disposed on both sides of the active part and on the top surface of each of the plurality of active parts together form a three-sided capacitor structure. The first electrode plate, the second insulation layer, and the second electrode plate may also form another three-sided capacitor structure on both sides and the top surface of each of the plurality of active parts, thereby increasing capacitance density. At the same time, because the first electrode plate is an interconnected integral electrode plate and the second electrode plate is another interconnected integral electrode plate, conductive plugs can be arranged only in a peripheral area of the substrate, thereby substantially reducing the number of conductive plugs required for the electrical interconnection and minimizing occurrence of short circuits in the electrical interconnection. The first electrode plate and the second electrode plate disposed in a center area are ensured to have large operation areas. Thus, the capacitance is increased and the process of forming the electrical interconnection has less impact on the device structure in the center area.

Correspondingly, the present disclosure also provides a capacitor formed by the above-described method.

Referring to FIGS. 19 to 21, the capacitor includes: a substrate 102 including a center area I and a peripheral area II surrounding the center area I; a plurality of active parts 101 disposed in the center area I and the peripheral area II, where first grooves 103 are formed between adjacent active parts 101; and an electrode structure (not labeled) disposed on the surface of the substrate 102, where the electrode structure includes a first insulation layer 110, a first electrode plate 121, a second insulation layer 125, and a second electrode plate 130 that are stacked in sequence, and is disposed in the first grooves 103 and on the top surface of each of the plurality of active parts 101; one or more first openings 161 disposed in the second electrode plate 130, the second insulation layer 125, the first electrode plate 121, and the first insulation layer 110 in the peripheral area II, where the one or more first openings 161 expose a part of the top surface of each of the plurality of active parts 101 in the peripheral area II; one or more second openings 162 disposed in the second electrode plate 130 and the second insulation layer 125 in the peripheral area II, where the one or more second openings 162 expose a part of the surface of the first electrode plate 121 in the peripheral area II; a plurality of first plugs 151 disposed in the one or more first openings 161; and a plurality of second plugs 152 disposed in the one or more second openings 162.

In some embodiments, the material of the plurality of active parts 101 includes silicon. The material of the first electrode plate 121 includes polysilicon. The material of the second electrode plate 130 includes polysilicon.

In some embodiments, the electrode structure further includes: a first insulation layer 110 disposed on the surface of the substrate 102, the sidewall surfaces on both sides of each of the plurality of active parts 101, and the top surface of each of the plurality of active parts 101; a first electrode plate 121 disposed on the surface of the insulation layer 110, where the first electrode plate 121 is disposed in the first grooves 103 and on the top surface of each of the plurality of active parts 101, and the first electrode plate 121 disposed in the first grooves 103 includes second grooves 120; a second insulation layer 125 disposed on the surface of the first electrode plate 121; a second electrode plate 130 disposed on the surface of the second insulation layer 125, where the second electrode plate 130 is disposed in the second grooves 120 and on the top surface of each of the plurality of active parts 101.

In some embodiments, the plurality of first plugs 151 are disposed on the top surface of each of the plurality of active parts 101 exposed by the one or more first openings 161. The plurality of second plugs 152 are disposed on the surface of the first electrode plate 121 exposed by the one or more second openings 162.

In some embodiments, the capacitor further includes: a plurality of third plugs 153 disposed on the surface of the second electrode plate 130 in the peripheral area II.

In some other embodiments, the plurality of third plugs 153 may also be disposed on the surface of the second electrode plate in the isolation area III.

In some embodiments, the bottom surface of the plurality of first plugs 151 is lower than the bottom surface of the plurality of second plugs 152, and the bottom surface of the plurality of second plugs 152 is lower than the bottom surface of the plurality of third plugs 153.

In some embodiments, the one or more first openings 161 extend in a direction perpendicular to a direction in which the one or more second openings 162 extend.

In some embodiments, the spacing between adjacent active parts 101 ranges from 100 nanometers to 1,000 nanometers.

In some embodiments, a thickness of the first electrode plate 121 in the center area I in a direction perpendicular to the sidewall of each of the plurality of active parts 101 ranges from 20 nanometers to 200 nanometers. A thickness of the first electrode plate 121 in the peripheral area II in the direction perpendicular to the sidewall of each of the plurality of active parts 101 ranges from 40 nanometers to 200 nanometers.

In some embodiments, a distance from the top surface of the second electrode plate 130 to the top surface of the second insulation layer 125 ranges from 20 nanometers to 200 nanometers.

In some embodiments, the substrate 102 further includes an isolation area III surrounding the center area I and the peripheral area II. The isolation area III includes an isolation structure 112 therein. The surface of the isolation structure 112 is flush with the top surface of first electrode plate 121. The second electrode plate 130 and the second insulation layer 125 are also disposed on the surface of the isolation structure 112.

In some embodiments, the capacitor further includes: a first electrical interconnection layer (not shown) electrically connecting the plurality of third plugs 153 and the plurality of first plugs 151; and a second electrical interconnection layer (not shown) electrically connecting the plurality of second plugs 152.

In some embodiments, the first grooves 103 between adjacent active parts 101 include the first insulation layer 110, the first electrode plate 121, the second insulation layer 125, and the second electrode plate 130. The first electrode plate 121 and the first insulation layer 110 are also disposed on the top surface of each of the plurality of active parts 101. The second electrode plate 130 and the second insulation layer 125 are also disposed on the surface of the first electrode plate 121. Thus, the plurality of active parts 101, the first insulation layer 110, and the first electrode plate 121 together form a three-sided capacitor structure on both sides and the top surface of each of the plurality of active parts 101, and the first electrode plate 121, the second insulation layer 125, and the second electrode plate 130 together also form a three-sided capacitor structure on both sides and the top surface of each of the plurality of active parts 101, thereby efficiently utilizing the vertical operation space of the chip. The horizontal operation area of the chip is controlled to be small to increase the capacitance density while maintaining a large capacitor plate area. At the same time, the first electrode plate 121 is an interconnected integral electrode plate, and the second electrode plate 130 is also an interconnected integral electrode plate. The conductive plugs can be arranged only in the peripheral area II of the substrate 102. Thus, the number of conductive plugs required for the electrical interconnection is substantially reduced, the occurrence of short circuits of the electrical interconnection is minimized, the first electrode plate 121 and the second electrode plate 130 in the center area I are ensured to occupy a large operation area, the capacitance density is increased, and the impact of the electrical interconnection process on the device structure in the center area I is also reduced.

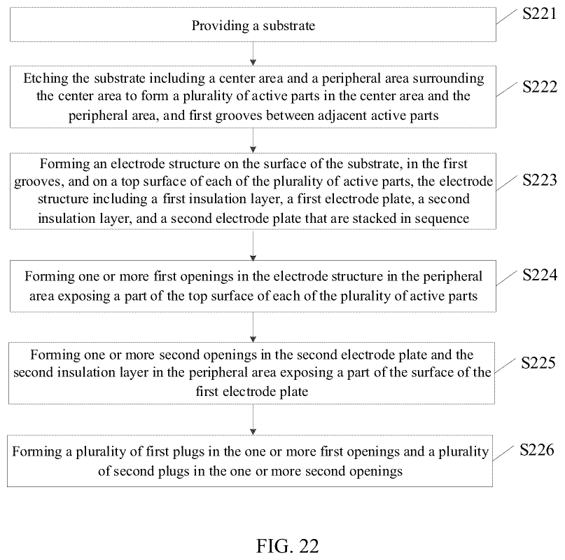

The present disclosure also provides a method for forming a capacitor. FIG. 22 is a flowchart of a method of forming an exemplary capacitor according to some embodiments of the present disclosure. As shown in FIG. 22, the method includes the following processes.

At S221, a substrate is provided.

At S222, the substrate including a center area and a peripheral area surrounding the center area is etched to form a plurality of active parts in the center area and the peripheral area, and first grooves between adjacent active parts.

At S223, an electrode structure is formed on the surface of the substrate, in the first grooves, and on the top surface of each of the plurality of active parts, the electrode structure including a first insulation layer, a first electrode plate, a second insulation layer, and a second electrode plate that are stacked in sequence.

At S224, one or more first openings are formed in the electrode structure in the peripheral area exposing a part of the top surface of each of the plurality of active parts

At S225, one or more second openings are formed in the second electrode plate and the second insulation layer in the peripheral area exposing a part of the surface of the first electrode plate.

At S226, a plurality of first plugs are formed in the one or more first openings and a plurality of second plugs are formed in the one or more second openings.

In some embodiments, the material of the plurality of active parts includes silicon. The material of the first electrode plate includes polysilicon. The material of the second electrode plate includes polysilicon.

In some embodiments, the electrode structure is formed by: forming the first insulation layer on the surface of the substrate exposed by the first grooves, the sidewall surfaces on both sides of each of the plurality of active parts, and the top surface of each of the plurality of active parts; forming the first electrode plate on the surface of the first insulation layer, the first electrode plate being disposed in the first grooves and on the top surface of each of the plurality of active parts, and the first electrode plate disposed in the first grooves includes second grooves; forming the second insulation layer on the surface of the first electrode plate; and forming the second electrode plate on the surface of the second insulation layer in the second grooves and on the top surface of each of the plurality of active parts.

In some embodiments, the first electrode plate, the second insulation layer, and the second electrode plate are formed by: forming a first material layer in the first grooves and on the surface of the first insulation layer on top of each of the plurality of active parts; forming the second grooves in the first material layer, the bottom of the second grooves being higher than the surface of the substrate, and the first material layer being the first electrode plate; forming the second insulation layer in the second grooves and one the top surface of the first electrode plate; and filling the second electrode plate in the second grooves, the second electrode plate also being disposed on the surface of the second insulation layer on top of the first electrode plate.

In some embodiments, the plurality of first plugs are formed on the top surface of each of the plurality of active parts exposed in the one or more first openings. The plurality of second plugs are formed on the surface of the first electrode plate exposed in the one or more second openings.

In some embodiments, the method further includes: forming a plurality of third plugs on the surface of the second electrode plate.

In some embodiments, the bottom surface of the plurality of first plugs is lower than the bottom surface of the plurality of second plugs. The bottom surface of the plurality of second plugs is lower than the bottom surface of the plurality of third plugs.

In some embodiments, after the one or more first openings and the one or more second openings are formed and before forming the plurality of first plugs, the plurality of second plugs, and the plurality of third plugs, the method further includes: forming a interlayer dielectric layer in the one or more first openings and the one or more second openings, and on the surface of the second electrode plate, wherein the plurality of first plugs, the plurality of second plugs, and the plurality of third plugs are formed in the interlayer dielectric layer.

In some embodiments, the substrate further includes an isolation area surrounding the center area and the peripheral area. The method of forming the capacitor further includes: forming an isolation structure in the isolation area, the surface of the isolation structure being flush with the top surface of the first electrode plate. The second electrode plate and the second insulation layer are further disposed on the surface of the isolation structure.

In some embodiments, the substrate further includes an isolation area surrounding the center area and the peripheral area. The plurality of third plugs are formed on the surface of the second electrode plate in the peripheral area or the isolation area.

In the embodiments of the present disclosure, the capacitor is formed by: etching the substrate to form various areas and a plurality of active parts, with first grooves between adjacent active parts; and forming a first insulation layer, a first electrode plate, a second insulation layer, and a second electrode plate in the first grooves. The first electrode plate and the first insulation layer are disposed on a top surface of each of the plurality of active parts, and the second electrode plate and the second insulation layer are disposed on a surface of the first electrode plate. As such, the plurality of active parts, and the first insulation layer, and the first electrode plate disposed on both sides of the active part and on the top surface of each of the plurality of active parts together form a three-sided capacitor structure. The first electrode plate, the second insulation layer, and the second electrode plate may also form another three-sided capacitor structure on both sides and the top surface of each of the plurality of active parts, thereby increasing capacitance density. At the same time, because the first electrode plate is an interconnected integral electrode plate and the second electrode plate is another interconnected integral electrode plate, conductive plugs can be arranged only in a peripheral area of the substrate, thereby substantially reducing the number of conductive plugs required for the electrical interconnection and minimizing occurrence of short circuits in the electrical interconnection. The first electrode plate and the second electrode plate disposed in a center area are ensured to have large operation areas. Thus, the capacitance is increased and the process of forming the electrical interconnection has less impact on the device structure in the center area.

The above description of the disclosed embodiments is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments shown herein, but is to be accorded the broadest scope consistent with the principles and novel features disclosed herein.

What is claimed is:

1. A capacitor, comprising:
a substrate including a center area and a peripheral area surrounding the center area;
a plurality of active parts disposed in the center area and the peripheral area, first grooves being formed between adjacent active parts;
an electrode structure including a first insulation layer, a first electrode plate, a second insulation layer, and a second electrode plate that are stacked in sequence, the electrode structure being disposed in the first grooves and on a top surface of each of the plurality of active parts;
one or more first openings disposed in the electrode structure in the peripheral area exposing a part of the top surface of each of the plurality of active parts in the peripheral area;
one or more second openings disposed in the second electrode plate and the second insulation layer in the peripheral area exposing a part of the surface of the first electrode plate in the peripheral area; and
a plurality of first plugs disposed in the one or more first openings and a plurality of second plugs disposed in the one or more second openings.

2. The capacitor according to claim 1, wherein:
the material of the plurality of active parts includes silicon;
the material of the first electrode plate includes polysilicon; and
the material of the second electrode plate includes polysilicon.

3. The capacitor according to claim 1, wherein the electrode structure comprises:
the first insulation layer disposed on the surface of the substrate, the sidewall surfaces on both sides of each of the plurality of active parts, and the top surface of each of the plurality of active parts;
the first electrode plate disposed on the surface of the first insulation layer, the first electrode plate being disposed in the first grooves and on the top surface of each of the plurality of active parts, and the first electrode plate disposed in the first grooves includes second grooves;
the second insulation layer disposed on the surface of the first electrode plate; and
the second electrode plate disposed on the surface of the second insulation layer, the second electrode plate being disposed in the second grooves and on the top surface of each of the plurality of active parts.

4. The capacitor according to claim 1, wherein:
the plurality of first plugs are disposed on the top surface of each of the plurality of active parts exposed by the one or more first openings; and
the plurality of second plugs are disposed on the surface of the first electrode plate exposed by the one or more second openings.

5. The capacitor according to claim 1, further comprising:
a plurality of third plugs disposed on the surface of the second electrode plate.

6. The capacitor according to claim 5, wherein:
the bottom surface of the plurality of first plugs is lower than the bottom surface of the plurality of second plugs; and
the bottom surface of the plurality of second plugs is lower than the bottom surface of the plurality of third plugs.

7. The capacitor according to claim 1, wherein:
the one or more first openings extend in a direction perpendicular to a direction in which the one or more second openings extend.

8. The capacitor according to claim 1, wherein:
a thickness of the first electrode plate in the center area in a direction perpendicular to the sidewall of each of the plurality of active parts ranges from 20 nanometers to 200 nanometers; and
a thickness of the first electrode plate in the peripheral area in the direction perpendicular to the sidewall of each of the plurality of active parts ranges from 40 nanometers to 200 nanometers

9. The capacitor according to claim 1, wherein:
the substrate further includes an isolation area surrounding the center area and the peripheral area, the peripheral area including an isolation structure, the surface of the isolation structure being flush with the top surface of the first electrode plate; and
the second electrode plate and the second insulation layer are further disposed on the surface of the isolation structure.

10. The capacitor according to claim 5, further comprising:
a first electrical interconnection layer electrically connecting the plurality of third plugs and the plurality of first plugs; and
a second electrical interconnection layer electrically connecting the plurality of second plugs.

11. A method of forming a capacitor, comprising:
providing a substrate;
etching the substrate including a center area and a peripheral area surrounding the center area to form a plurality of active parts in the center area and the peripheral area, and first grooves between adjacent active parts;
forming an electrode structure on the surface of the substrate, in the first grooves, and on the top surface of each of the plurality of active parts, the electrode structure including a first insulation layer, a first electrode plate, a second insulation layer, and a second electrode plate that are stacked in sequence;
forming one or more first openings in the electrode structure in the peripheral area exposing a part of the top surface of each of the plurality of active parts;
forming one or more second openings in the second electrode plate and the second insulation layer in the peripheral area exposing a part of the surface of the first electrode plate; and
forming a plurality of first plugs in the one or more first openings and a plurality of second plugs in the one or more second openings.

12. The method according to claim 11, wherein:
the material of the plurality of active parts includes silicon;
the material of the first electrode plate includes polysilicon; and
the material of the second electrode plate includes polysilicon.

13. The method according to claim 11, wherein the electrode structure is formed by:
forming the first insulation layer on the surface of the substrate exposed by the first grooves, the sidewall surfaces on both sides of each of the plurality of active parts, and the top surface of each of the plurality of active parts;
forming the first electrode plate on the surface of the first insulation layer, the first electrode plate being disposed in the first grooves and on the top surface of each of the plurality of active parts, and the first electrode plate disposed in the first grooves includes second grooves;
forming the second insulation layer on the surface of the first electrode plate; and
forming the second electrode plate on the surface of the second insulation layer in the second grooves and on the top surface of each of the plurality of active parts.

14. The method according to claim 13, wherein the first electrode plate, the second insulation layer, and the second electrode plate are formed by:
forming a first material layer in the first grooves and on the surface of the first insulation layer on top of each of the plurality of active parts;
forming the second grooves in the first material layer, the bottom of the second grooves being higher than the surface of the substrate, and the first material layer being the first electrode plate;
forming the second insulation layer in the second grooves and one the top surface of the first electrode plate; and
filling the second electrode plate in the second grooves, the second electrode plate also being disposed on the surface of the second insulation layer on top of the first electrode plate.

15. The method according to claim 11, wherein:
the plurality of first plugs are formed on the top surface of each of the plurality of active parts exposed in the one or more first openings; and
the plurality of second plugs are formed on the surface of the first electrode plate exposed in the one or more second openings.

16. The method according to claim 11, further comprising:
forming a plurality of third plugs on the surface of the second electrode plate.

17. The method according to claim 16, wherein:
the bottom surface of the plurality of first plugs is lower than the bottom surface of the plurality of second plugs; and
the bottom surface of the plurality of second plugs is lower than the bottom surface of the plurality of third plugs.

18. The method according to claim 17, wherein:
after the one or more first openings and the one or more second openings are formed and before forming the plurality of first plugs, the plurality of second plugs, and the plurality of third plugs, the method further includes: forming a interlayer dielectric layer in the one or more first openings and the one or more second openings, and on the surface of the second electrode plate, wherein the plurality of first plugs, the plurality of second plugs, and the plurality of third plugs are formed in the interlayer dielectric layer.

19. The method according to claim 11, wherein:
the substrate further includes an isolation area surrounding the center area and the peripheral area;
the method of forming the capacitor further includes: forming an isolation structure in the isolation area, the surface of the isolation structure being flush with the top surface of the first electrode plate; and
the second electrode plate and the second insulation layer are further disposed on the surface of the isolation structure.

20. The method according to claim 16, wherein:
the substrate further includes an isolation area surrounding the center area and the peripheral area; and
the plurality of third plugs are formed on the surface of the second electrode plate in the peripheral area or the isolation area.
